(19) United States
(12) Patent Application Publication
(10) Pub. No.: US 2002/0195683 A1
(43) Pub. Date: Dec. 26, 2002

(54) Semiconductor device and method for manufacturing the same

(76) Inventors: Yeong-kwan Kim, Seoul (KR); Heung-soo Park, Seoul (KR); Young-wook Park, Kyungki-do (KR); Sang-in Lee, Kyungki-do (KR); Yoon-hee Chang, Seoul (KR); Jong-ho Lee, Kyungki-do (KR); Sung-je Choi, Seoul (KR); Seung-hwan Lee, Seoul (KR); Jae-soon Lim, Seoul (KR); Joo-won Lee, Kyungki-do (KR)

Correspondence Address: The Law Office of Eugene M Lee PLLC, 1101 Wilson Boulevard, Suite 2000, Arlington, VA, 22209, US

(21) Appl. No.: 09/535,949

(22) Filed: Mar. 27, 2000

(51) Int. Cl. H01L 29/00

(52) U.S. Cl. 257/532

(57) ABSTRACT

A semiconductor device includes a first electrode formed of a silicon-family material, a dielectric layer formed by sequentially supplying reactants on the first electrode, and a second electrode having a work function larger than that of the first electrode, with the second electrode being formed on the dielectric layer. The first electrode and the second electrode can be a lower electrode and an upper electrode, respectively, in a capacitor structure. Also, the first electrode and the second electrode can be a silicon substrate and a gate electrode, respectively, in a transistor structure. A stabilizing layer, which is, for example, a silicon oxide layer, a silicon nitride layer, or a composite layer of the silicon oxide layer and the silicon nitride layer, for facilitating the formation of the dielectric layer by hydrophilizing the surface of the first electrode, may be formed on the first electrode. The dielectric layer can be formed by an atomic layer deposition method. Accordingly, in the semiconductor device, it is possible to improve the insulating characteristic of the dielectric layer and to increase a capacitance value in the capacitor structure.

### CROSS-REFERENCE TO RELATED APPLICATIONS

This application is based upon and claims priority from Korean Patent Application No. 99-33520 filed Aug. 14, 1999, the contents of which are incorporated herein by reference.

### BACKGROUND OF THE INVENTION

1. Field of the Invention

The present invention relates to a semiconductor device and a method for manufacturing the same. More particularly, the present invention relates to a semiconductor device in which it is possible to improve the insulating characteristics of a high dielectric layer (a dielectric layer with a large dielectric constant) when a semiconductor material is used as a lower electrode. The invention also relates to a method for manufacturing the same.

2. Description of the Related Art

Normally, semiconductor devices have a structure in which a dielectric layer is formed between a lower electrode and an upper electrode. For example, a transistor structure in which a dielectric layer (a gate insulating layer) and a gate electrode are sequentially formed on a silicon substrate, which operates as the lower electrode. A capacitor structure having the dielectric layer and an upper electrode are sequentially formed on the lower electrode.

The insulating characteristic of the dielectric layer which exists between the upper electrode and the lower electrode is very important. For example, the breakdown voltage characteristic of a transistor is influenced by the insulating characteristic of the dielectric layer in the transistor structure. Capacitance values vary according to the insulating characteristic of the dielectric layer in the capacitor structure.

In particular, the capacitance value becomes large when the surface area and the dielectric constant of the dielectric layer in the capacitor structure are large. Thus, a polysilicon layer by which a three-dimensional structure is easily realized is used as the lower electrode. Also, a tantalum oxide layer (Ta₂O₅) or a BST (BaSrTiO₃) layer having a high dielectric constant is used as the high dielectric layer. However, when the high dielectric layer, such as the tantalum oxide layer (Ta₂O₅) or the BST (BaSrTiO₃) layer, is used as the dielectric layer, processes become complicated since subsequent processes are needed in order to obtain a stable capacitor. In the case of the Ta₂O₅ or the BST layer being used as the dielectric layer, the material of the upper and lower electrodes must be changed. Therefore, in the capacitor structure, it is necessary to improve the insulating characteristic of the high dielectric layer when a polysilicon layer is used as the lower electrode.

### SUMMARY OF THE INVENTION

Thus, to overcome the problems noted above with the prior art, the present invention provides a semiconductor device wherein it is possible to improve the insulating characteristic of a high dielectric layer when a silicon-family material is used as a lower electrode.

Another feature of the present invention is to provide a method suitable for manufacturing the semiconductor device.

Accordingly, to achieve the features noted above, a semiconductor device is provided, which includes a first electrode formed of a silicon-family material, a dielectric layer formed on the first electrode by sequentially supplying reactants, and a second electrode having a work function larger than that of the first electrode formed of the silicon-family material. The second electrode is formed on the dielectric layer.

In addition, the present invention provides a method for manufacturing a semiconductor device, with the method including the steps of forming a first electrode formed of a silicon-family material on a semiconductor substrate, forming a dielectric layer on the first electrode by sequentially supplying reactants, and forming a second electrode having a work function larger than that of the first electrode formed of the silicon-family material, with the second electrode being formed on the dielectric layer.

The first electrode and the second electrode can be respectively used as a lower electrode and an upper electrode in a capacitor structure. Also, the first electrode and the second electrode can be respectively used as a silicon substrate and a gate electrode in a transistor structure.

The second electrode can be formed of a metal layer, a refractory metal layer, an aluminum layer, a conductive oxide layer, a combination of the above, or a double layer in which a material layer having a work function larger than that of the silicon-family material and a polysilicon layer doped with impurities are sequentially formed.

A stabilizing layer, such as a silicon oxide layer, a silicon nitride layer, or a composite layer of the silicon oxide layer and the silicon nitride layer, for facilitating the formation of the dielectric layer by hydrophilizing the surface of the first electrode can also be formed on the first electrode. The dielectric layer can be formed by an atomic layer deposition method.

According to the present invention, the silicon-family material is used as the lower electrode. The dielectric layer is formed by an atomic layer deposition method, and the upper electrode is formed of a material layer having a work function larger than that of the lower electrode. Accordingly, it is possible to improve the insulating characteristic of the dielectric layer and to increase the capacitance value in the capacitor structure.

### BRIEF DESCRIPTION OF THE DRAWINGS

These and other features, characteristics, and advantages of the present invention will become more apparent by describing in detail preferred embodiments thereof with reference to the attached drawings. In the drawings:

FIG. 1 is a cross-sectional view showing a semiconductor device according to a first embodiment of the present invention;

FIG. 2 shows a cross-sectional view of a semiconductor device according to a second embodiment of the present invention;

FIGS. 3A-3C and 4A-4C schematically show the barrier heights and equivalent circuits of a conventional capacitor and the capacitor according to the first embodiment, respectively;

FIG. 5 is a graph showing leakage current densities according to a voltage, of a conventional capacitor (SIS) and a MIS capacitor of the present invention;

FIG. 6 is a graph showing barrier heights of the conventional SIS capacitor and the MIS capacitor according to the present invention;

FIGS. 7 and 8 are graphs showing the leakage current densities as a function of voltage of the MIS capacitor of the present invention and the conventional SIS capacitor, respectively;

FIG. 9 is a graph showing processes of supplying and purging the respective reactants while the dielectric layer of the capacitor shown in FIG. 1 is formed by an atomic layer deposition method;

FIG. 10 is a graph showing the uniform thickness of the dielectric layer formed by the atomic layer deposition method of the present invention;

FIGS. 11A and 11B show the x-ray photoelectron spectroscopy (XPS) peak value of the dielectric layer formed by the atomic layer deposition method according to the present invention;

FIGS. 12 and 13 are cross-sectional views illustrating a method for manufacturing the capacitor of the semiconductor device shown in FIG. 1; and

FIG. 14 is a graph showing the thicknesses of an aluminum oxide layer versus number of cycles in cases where a stabilizing layer is represented by the line (a), and is not formed on the surface of the lower electrode in the MIS capacitor of the present invention.

### DESCRIPTION OF THE ILLUSTRATIVE EMBODIMENTS

Illustrative embodiments of the present invention will now be described with reference to the accompanying FIGURES.

FIG. 1 is a cross-sectional view showing a semiconductor device according to a first embodiment of the present invention. More specifically, the semiconductor device according to the present invention has a capacitor structure. Namely, the semiconductor device of the present invention includes lower electrode 33 of a capacitor, dielectric layer 37, and upper electrode 39 of the capacitor used as a second electrode. All elements, lower electrode 33, dielectric layer 37 and upper electrode 39 are formed on semiconductor substrate 31, which is, i.e., a silicon substrate used as a first electrode. In FIG. 1, reference numeral 32 denotes an inter level dielectric layer.

Lower electrode 33 is formed of a layer made of a silicon-family material from which a three-dimensional structure is easily formed, e.g., a polysilicon layer doped with impurities such as phosphorus (P). Dielectric layer 37 is formed by an atomic layer deposition method in which reactants are sequentially supplied. Since dielectric layer 37 is formed by an atomic layer deposition method, the dielectric layer 37 has an excellent step coverage characteristic. Dielectric layer 37 is formed of an aluminum oxide, an aluminum hydroxide, Ta₂O₅ , BST (BaSrTiO₃), SrTiO₃, PbTiO₃, PZT (PbZrxTi₁₋ₓO₃), PLZT (PZT doped with La), Y₂O₃, CeO₂, Nb₂O₅, TiO₂, ZrO₂, HfO₂, SiO₂, SiN, Si₃N₄ or any combination of the above. Upper electrode 39 is formed of a layer of material having a work function larger than that of lower electrode 33 formed of the silicon-family material. Upper electrode 39 is formed of a metal layer such as Al, Ni, Co, Cu, Mo, Rh, Pd, Sn, Au, Pt, Ru, and Ir, a refractory metal layer such as Ti, TiN, TiAlN, TaN, TiSiN, WN, WBN, CoSi, and W, a conductive oxide layer such as RuO₂, RhO₂, and IrO₂, combinations of the above, or a double layer in which a material layer having a work function larger than that of the silicon-family material and a polysilicon layer doped with impurities are sequentially formed.

When upper electrode 39 has a work function larger than that of the lower electrode 33, it is possible to improve the insulating characteristic of the dielectric layer by reducing the amount of current which flows from the lower electrode 33 to the upper electrode 39 as mentioned below.

Furthermore, in the semiconductor device according to the present invention, stabilizing layer 35, which is, e.g., a silicon oxide layer, a silicon nitride layer, or a composite layer of the silicon oxide and the silicon nitride layers, facilitates the formation of dielectric layer 37, and is formed on the lower electrode 33 of the capacitor. For example, when the dielectric layer is formed using an atomic layer deposition method, stabilizing layer 35 is a hydrophilic layer which hydrophilizes the surface of lower electrode 33 in the case where the reactant supplied on lower electrode 33 is a hydrophilic material.

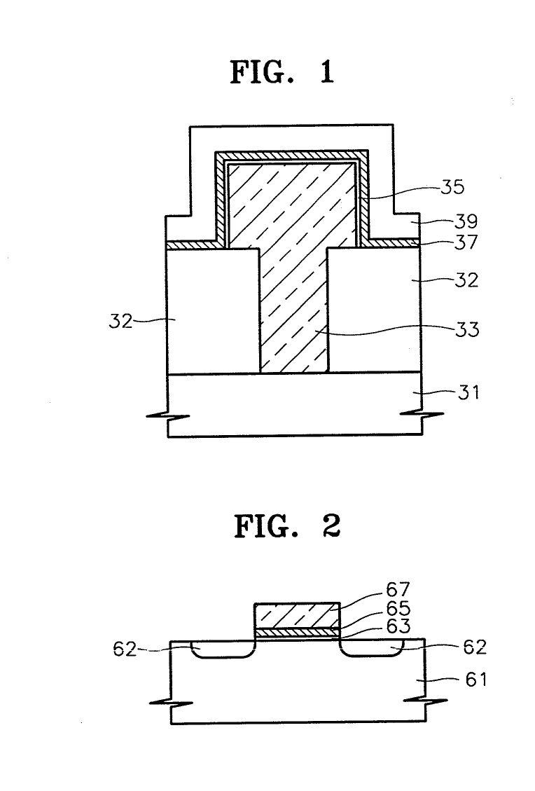

FIG. 2 shows a cross-sectional view of a semiconductor device according to a second embodiment of the present invention. To be specific, the semiconductor device according to the second embodiment of the present invention has a transistor structure rather than a capacitor structure as in FIG. 1. The semiconductor device according to the present invention includes silicon substrate 61, which is doped with impurities such as phosphorus (P), arsenic (As), boron (Br), and fluorine (F), used as the first electrode, gate insulating layer 65, used as the dielectric layer, and gate electrode 67, used as the second electrode.

Namely, in the semiconductor device according to the second embodiment of the present invention, silicon substrate 61 and gate electrode 67, respectively, correspond to the lower electrode and the upper electrode, compared with the semiconductor device according to the first embodiment of the present invention. In FIG. 2, reference numeral 62, which is an impurity doping region, denotes a source or drain region.

Gate insulating layer 65 is formed by an atomic layer deposition method including the sequential supply of reactants. Since gate insulating layer 65 is formed by an atomic layer deposition method, gate insulating layer 65 has an excellent step coverage characteristic. Gate insulating layer 65 is formed of an aluminum oxide, an aluminum hydroxide, Ta₂O₅, BST (BaSrTiO₃), SrTiO₃, PbTiO₃, PZT, PLZT, Y₂O₃, CeO₂, Nb₂O₅, TiO₂, ZrO₂, HfO₂, SiO₂, SiN, Si₃N₄or any combination thereof.

Gate electrode 67 is formed of a layer of material having a work function larger than that of lower electrode 61, which is formed of the silicon-family material. Gate electrode 67 is formed of a metal layer such as Al, Ni, Co, Cu, Mo, Rh, Pd, Sn, Au, Pt, Ru, and Ir, a refractory metal layer such as Ti, TiN, TiAlN, TaN, TiSiN, WN, WBN, CoSi, and W, a conductive oxide layer such as RuO₂, RhO₂, and IrO₂, any combination thereof, or a double layer in which a layer of material having a work function larger than that of the silicon-family material and a polysilicon layer doped with impurities are sequentially formed.

When gate electrode 67 has a work function larger than that of the silicon substrate 61, it is possible to improve the insulating characteristic of gate insulating layer 65 since it is possible to reduce the amount of current which flows from silicon substrate 61 to gate electrode 67.

Furthermore, in the semiconductor device of the present invention, stabilizing layer 63, which is, e.g., a silicon oxide layer, a silicon nitride layer, or a composite layer of the silicon oxide and the silicon nitride layers, for facilitating the formation of gate insulating layer 65, is formed on the silicon substrate 61. For example, when the dielectric layer is formed using an atomic layer deposition method, stabilizing layer 63 is a hydrophilic layer which hydrophilizes the surface of silicon substrate 61 in the case where the reactant supplied to silicon substrate 61 is a hydrophilic material.

The insulating characteristic of the dielectric layer will be described with reference to the first embodiment, i.e., the capacitor structure, for the sake of convenience. The description of the insulating characteristic of the dielectric layer can also be applied to the transistor structure in the second embodiment. That is to say, the lower electrode of the capacitor corresponds to the silicon substrate of the transistor and the upper electrode of the capacitor corresponds to the gate electrode of the transistor.

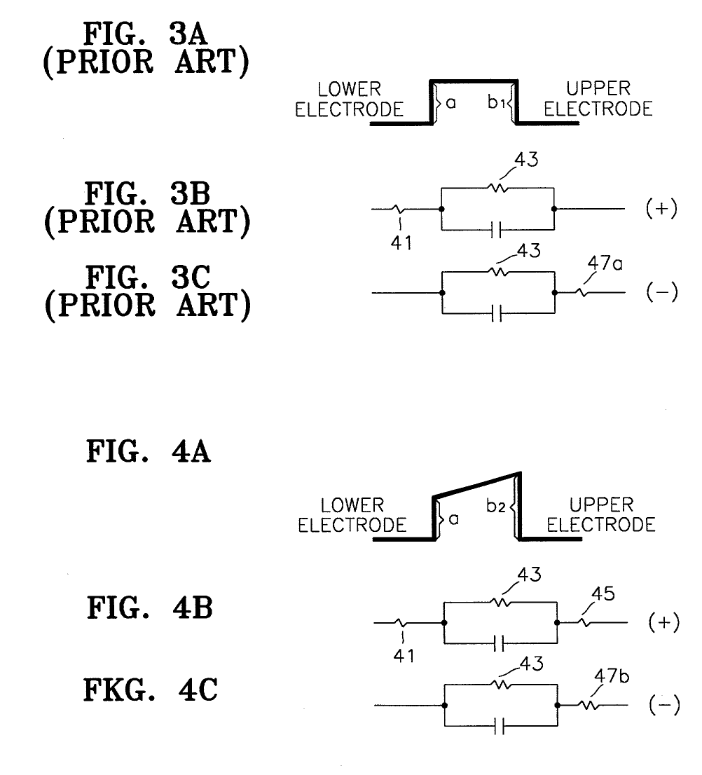

FIGS. 3A-3C and 4A-4C schematically show the barrier heights and equivalent circuits of a conventional capacitor and the capacitor of FIG. 1, respectively.

To be specific, FIGS. 3A-3C illustrate barrier height and equivalent circuit of the conventional capacitor. In the conventional capacitor shown in FIGS. 3A-3C, the upper and lower electrodes are formed of a polysilicon layer doped with impurities and the dielectric layer is formed of an aluminum oxide layer having a thickness of 60 Å using an atomic layer deposition method (SIS capacitor). FIGS. 4A-4C depict the barrier height and equivalent circuit of the capacitor of FIG. 1. In the capacitor of FIGS. 4A-4C, which is preferably a metal-insulator-semiconductor (MIS) capacitor, the lower electrode is formed of the polysilicon layer doped with impurities as the silicon-family material layer. The dielectric layer is formed of an aluminum oxide layer having a thickness of 60 Å using an atomic deposition method, and the upper electrode is formed of a TiN layer having a work function larger than that of the lower electrode. In the MIS capacitor of the present invention, the upper electrode can be formed of a double layer including the TiN layer and the polysilicon layer doped with impurities. In this case, the polysilicon layer doped with impurities controls the surface resistance from the viewpoint of the operation of the semiconductor device.

In FIGS. 3A-3C and 4A-4C, electrons which exist in the lower electrode can move to the upper electrode by passing through a first resistance component 41 corresponding to an initial barrier (a) and a second resistance component 43 of the dielectric layer when a positive bias is applied to the upper electrode.

In the capacitor of the present invention shown in FIGS. 4A-4C, the electrons pass through the initial barrier (a) and move toward the upper electrode having a higher barrier than the prior art capacitor when a positive bias voltage is applied to the upper electrode. At this time, since a slope is formed by the difference (b2-a) between the barrier of the lower electrode and the barrier of the upper electrode, this slope operates as a third resistance component 45 which prevents the flow of the electrons, thus preventing the electrons from flowing from the lower electrode to the upper electrode, and thus improving the insulating characteristic of the dielectric layer.

When a negative-bias voltage is applied to the upper electrode (FIGS. 3C and 4C), it is difficult for the electrons to move from the upper electrode to the lower electrode due to fourth resistance components 47a and 47b caused by large initial barriers b1 and b2. In particular, since the initial barrier height b2 of the capacitor of the present invention in FIG. 4 is higher than the initial barrier height b1 of the capacitor in FIG. 3, the fourth resistance component 47b of the present invention is larger than the conventional fourth resistance component 47a.

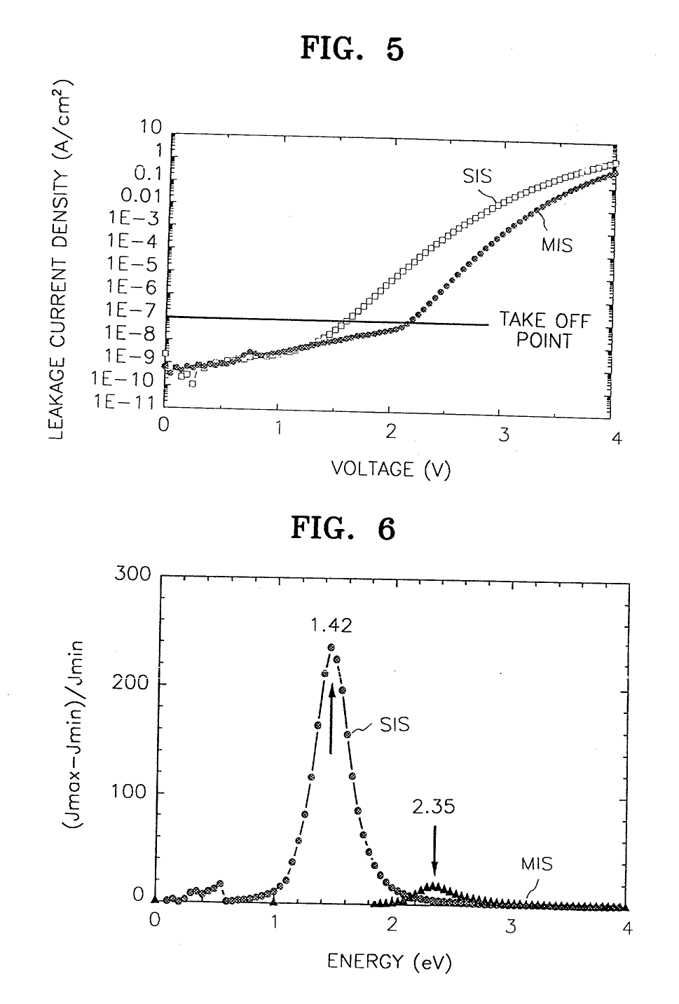

FIG. 5 is a graph showing leakage current densities according to voltage of the conventional SIS capacitor and the MIS capacitor of the present invention. FIG. 6 is a graph showing the barrier heights of the conventional SIS capacitor and the MIS capacitor of the present invention.

To be specific, as shown in FIG. 5, when the leakage current density is 1E-7A/cm², which is allowable in a general semiconductor device, the MIS capacitor of the present invention shows a take off point which is larger than that of the conventional SIS capacitor by 0.9 V. Such a phenomenon is caused by the difference between the barrier height of the lower electrode and the barrier height of the upper electrode as shown in FIGS. 4A and 6. In FIG. 6, the X axis denotes energy corresponding to the barrier height and a Y axis denotes the barrier height. Jmax denotes a current density at 125° C. and Jmin denotes a current density at 25° C. As shown in FIG. 6, a peak point at the positive bias voltage denotes energy corresponding to the barrier height. The peak point is 1.42 eV in the conventional SIS capacitor and 2.35 eV in the MIS capacitor according to the present invention.

The difference between the barrier height of the conventional SIS capacitor and the barrier height of the MIS capacitor according to the present invention is 0.93 eV. This difference is equivalent to the difference (b2-a) with reference to FIG. 4A. Therefore, the MIS capacitor according to the present invention has a take off point larger than that of the conventional SIS capacitor by the difference (b2-a). That is to say, since the MIS capacitor according to the present invention can withstand a leakage current density corresponding to a voltage difference of about 0.9 V, it is possible to reduce the thickness of the dielectric layer, and thus, to increase capacitance.

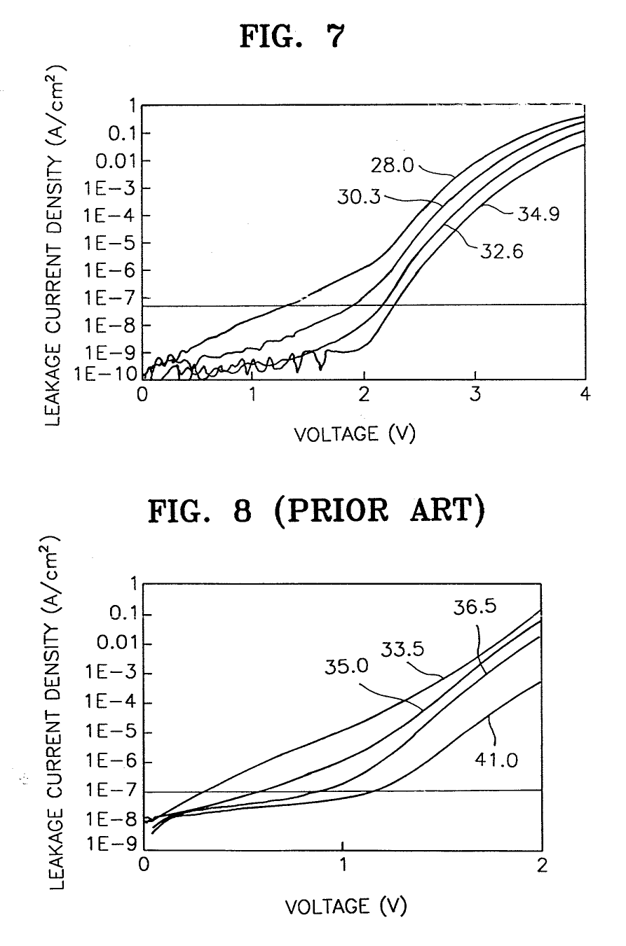

FIGS. 7 and 8 are graphs showing leakage current densities according to the voltage of the MIS capacitor and the conventional SIS capacitor, respectively.

To be specific, in a general reference value where the leakage current density is about 1E-7A/cm² and the voltage is 1.2 V, it is possible to allow an equivalent oxide layer to have the thickness of 28 Å in the case of the MIS capacitor according to the present invention and to allow an equivalent oxide layer to have the thickness of 41 Å in the case of the conventional SIS capacitor. The reason for this is because the take-off point of the MIS capacitor according to the present invention is larger than that of the SIS capacitor by a margin of about 0.9 V as mentioned above.

The method of manufacturing the semiconductor device according to the first embodiment, i.e., the capacitor structure, will now be described. The description of the method of manufacturing the semiconductor device of FIG. 1, the capacitor structure, can be applied to the structure of the transistor of the second embodiment. Namely, the lower electrode of the capacitor corresponds to the silicon substrate of the transistor and the upper electrode of the capacitor corresponds to the gate electrode of the transistor. A method of forming the capacitor dielectric layer according to the present invention will be described first.

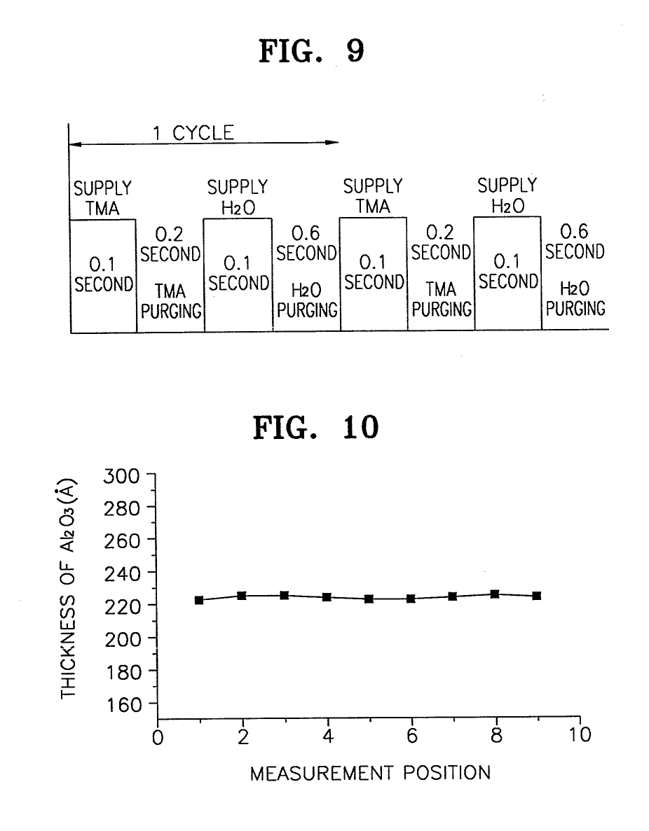

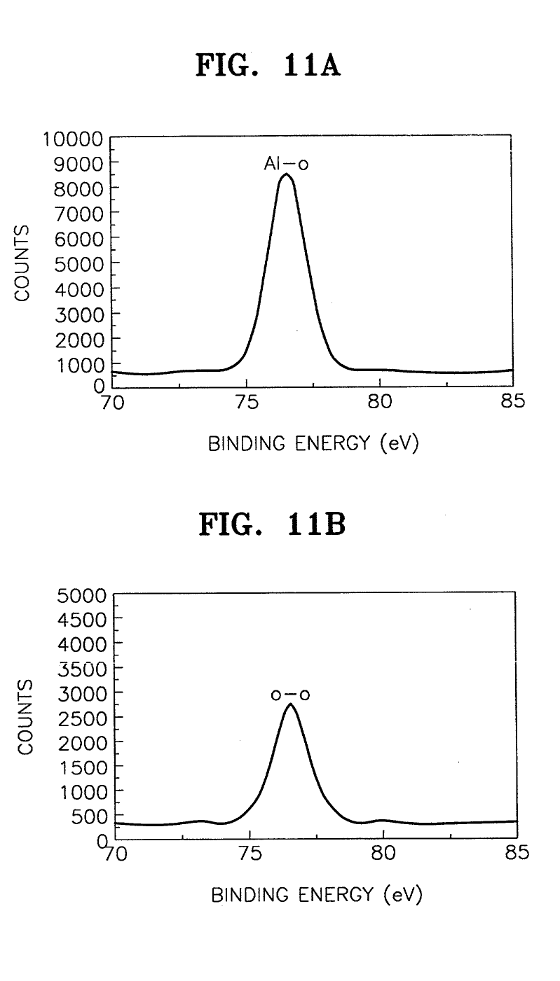

FIG. 9 is a graph showing processes of supplying and purging the respective reactants when the dielectric layer of the capacitor shown in FIG. 1 is formed by an atomic layer deposition method. FIG. 10 is a graph showing the uniform thickness of the dielectric layer formed by the atomic layer deposition method. FIGS. 11A-11B illustrate the x-ray photoelectron spectroscopy (XPS) peak value of the dielectric layer formed by the atomic layer deposition method.

More specifically, the capacitor dielectric layer according to the present invention is formed by the atomic layer deposition method, which has an excellent step coverage characteristic. In the present embodiment, a case where the dielectric layer is formed of an aluminum oxide layer will be used as an example. In the atomic layer deposition method, a cycle, where a reaction gas (a reactant) containing aluminum is supplied to a chamber, then purged by an inert gas, and then an oxidizing gas is supplied to the chamber, then purged by the inert gas, is repeated. Therefore, the atomic layer deposition method according to the present invention includes an atomic layer epitaxy (ALE), a cyclic chemical vapor deposition (CVD), a digital CVD, and an AlCVD.

To be specific, as shown in FIG. 9, the aluminum oxide layer is formed on the semiconductor substrate, for example, the silicon substrate, by repeating several times, the cycle in which the reactant containing aluminum such as TMA[Al(CH₃)₃], Al(CH₃)Cl, and AlCl₃is supplied to the chamber, then purged by the inert gas, and an oxidizing gas such as H₂O, N₂O, NO₂, and O₃ is supplied to the chamber, then purged by the inert gas. Namely, the aluminum oxide layer is formed by sequentially supplying a first reactant containing aluminum and a second reactant, which is an oxidizing gas. In the present embodiment, TMA is used as the reactant containing aluminum and H₂O gas is used as the oxidizing gas.

The aluminum oxide layer obtained by using these gases has an exceptional, uniform thickness according to the measurement positions shown in FIG. 10. In FIG. 10, among the points used for measurement, one point is at the center of a semiconductor wafer, four points are spaced apart by 90° on the circumference of a circle having a diameter of 1.75 inches, and the other four points are spaced apart by 90° on the circumference of a circle having a diameter of 3.5 inches.

When the aluminum oxide layer is XPS, measured as shown in FIGS. 11A and 11B, only Al—O and O—O peaks are found. This confirms that the aluminum oxide layer is formed of oxygen and aluminum. In FIGS. 11A and 11B, the X axis denotes binding energy and the Y axis denotes counts.

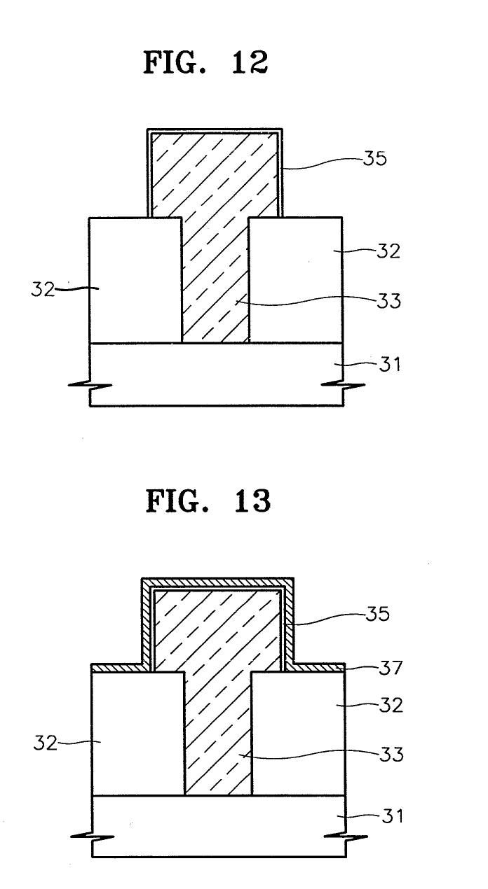

FIGS. 12 and 13 are cross-sectional views explaining a method of manufacturing the capacitor of the semiconductor device shown in FIG. 1.

FIG. 12 shows the steps of forming lower electrode 33 and stabilizing layer 35. Inter level dielectric layer 32 is formed on the semiconductor substrate, for example, the silicon substrate, and a hole is formed therein. Lower electrode 33 which contacts semiconductor substrate 31 through the contact hole is formed on semiconductor substrate 31, with inter level dielectric layer 32 also being formed on substrate 31. In particular, since lower electrode 33 is formed as a silicon-family material layer such as a polysilicon layer doped with impurities, lower electrode 33 can be formed to have various three-dimensional structures.

Stabilizing layer 35 is formed to a thickness of 1 to 40 Å to cover lower electrode 33 so that the dielectric layer, later formed on the surface of lower electrode 33, will be formed stably. Stabilizing layer 35 is formed of a silicon nitride layer using a nitrogen-family gas, by a process with a thermal hysteresis such as a rapid thermal process (RTP), an annealing process, or a plasma process, or using a reactant including silicon and nitrogen, at a temperature of 900° C. and for a period of three hours. Also, stabilizing layer 35 can be formed of a silicon oxide layer using an oxygen-family gas by an annealing process, a thermal ultra-violet (UV) process, or a plasma process. In the present embodiment, the RTP is performed for about 60 seconds or the UV ozone process is performed at a temperature of 450° C. for three minutes, using a nitrogen source, for example, NH₃ gas.

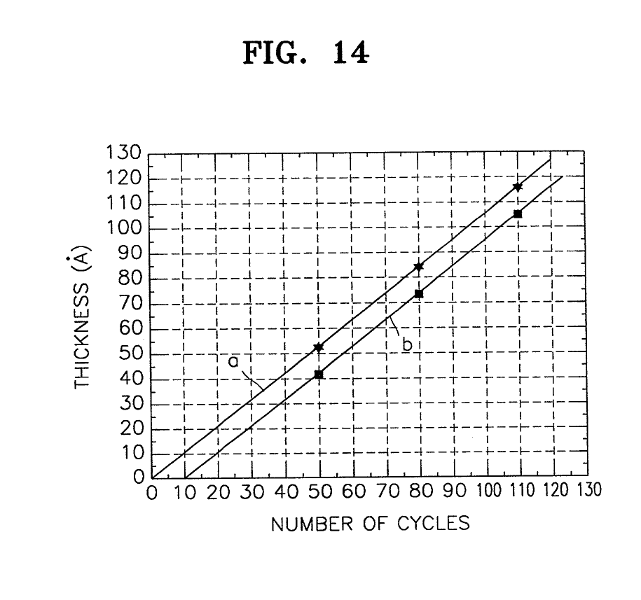

The role of stabilizing layer 35 will be described with reference to FIG. 14. FIG. 14 shows the thicknesses in Å of the aluminum oxide layer according to the number of cycles when the stabilizing layer is formed on the surface of the lower electrode (a) and when the stabilizing layer is not formed (b) on the surface of the lower electrode, as in the MIS capacitor according to the present invention.

Stabilizing layer 35 allows the dielectric layer to be stably formed in a subsequent process. Since the surface of the polysilicon, which is lower electrode 33, is doped with impurities and is generally in a hydrophobic state, when the dielectric layer is formed using water vapor as the oxidizing gas, it is not possible to stably form the aluminum oxide layer on hydrophobic lower electrode 33. That is, when stabilizing layer 35 is not formed as shown in (b) of FIG. 14, the aluminum oxide layer begins to grow after an incubation period of 10 cycles. However, when stabilizing layer 35 is formed, the surface of lower electrode 33 is changed to be hydrophilic. Accordingly, it is possible to stably form the aluminum oxide layer without the incubation period as shown in (a) of FIG. 14. In the present embodiment, stabilizing layer 35 is formed. However, the formation of the stabilizing layer may be omitted if necessary.

FIG. 13 shows steps of forming dielectric layer 37. The aluminum oxide layer is formed on lower electrode 33 to a thickness of about the size of one atom, for example, about 0.5 to 100Å, by sequentially injecting the aluminum source and the oxidizing gas into the chamber. Dielectric layer 37 is formed of the aluminum oxide layer to a thickness of about 10 to 300 Å by repeatedly performing the step of forming the aluminum oxide layer having a thickness of about the size of one atom. Dielectric layer 37 formed as mentioned above has an excellent step coverage due to the process characteristic of the atomic layer deposition method. For example, it is possible to have a step coverage of more than 98% in a structure having an aspect ratio of 9:1.

After forming dielectric layer 37, a post-thermal treatment is performed in order to remove impurities, to densify the dielectric layer, and to obtain a stoichiometric dielectric layer of high quality. The post-thermal treatment can be performed using an UV ozone process, nitrogen annealing, oxygen annealing, wet oxidation, an RTP using gas including oxygen or nitrogen such as N₂, NH₃, O₂, and N₂O, or vacuum annealing with a thermal hysteresis for a period of three hours at the temperature of 900° C. Results obtained by performing some of the above processes are shown in Table 1.

TABLE 1

| Thickness of | | | | |
|---|---|---|---|---|
| dielectric | Oxygen | UV ozone | Oxygen RTP | |
| layer ( ) | annealing | process | annealing | Nitrogen |
| 28 | 0.7 (28.6) | | 0.45 (27.6) | 0.9 (28.0) |
| 31 | 1.25 (30.9) | 1.55 (31.2) | 1.30 (30.2) | 1.6 (30.3) |
| 33 | 1.8 (33.1) | 2.05 (33.6) | 1.85 (32.5) | 2.1 (32.6) |

In Table 1, oxygen annealing is performed at a temperature of 750° C. for 30 minutes. The UV ozone process is performed with an energy of 20 milliwatts for 10 minutes. The oxygen RTP is performed at a temperature of 750° C. for three minutes. Nitrogen annealing is performed at a temperature of 750° C. for three minutes. The values of Table 1 denote refractive indices after the post-thermal treatment and the parenthesized numbers denote the thicknesses of the dielectric layer, in Å, after the thermal treatment. As shown in Table 1, samples on which the UV ozone process and nitrogen annealing are performed produce the best results in terms of the thickness of the dielectric layer and the refractive index. In the present embodiment, the post-thermal treatment is performed after forming the dielectric layer. However, performing the post-thermal treatment may be omitted.

Then, as shown in FIG. 1, upper electrode 39 is formed on dielectric layer 37. Upper electrode 39 is formed of the material layer having the work function larger than that of the lower electrode formed of the silicon-family material as mentioned above. Upper electrode 39 is formed of a metal layer such as Al, Ni, Co, Cu, Mo, Rh, Pd, Sn, Au, Pt, Ru, and Ir, a refractory metal layer such as Ti, TiN, TiAlN, TaN, TiSiN, WN, WBN, CoSi, and W, a conductive oxide layer such as RuO₂, RhO₂, and IrO₂, any combination of the above, or a double layer in which a material layer having a work function larger than that of the silicon-family material and a polysilicon layer doped with impurities are sequentially formed. In the present embodiment, the upper electrode is formed of a double layer, with a TiN layer and a polysilicon layer doped with impurities.

As mentioned above, in the semiconductor device according to the present invention, the dielectric layer is formed by an atomic layer deposition method and the upper electrode is formed of a material layer having a work function larger than that of the lower electrode when the normally-used silicon-family material layer, for example, the polysilicon layer doped with impurities, is used as the lower electrode. By doing so, it is possible to improve the insulating characteristic of the dielectric layer and to increase the capacitance value in the capacitor structure.

While the present invention has been described herein with reference to illustrative embodiments for particular applications, it should be understood that the invention is not limited thereto. Those having ordinary skill in the art and access to the teachings provided herein will recognize additional modifications, applications, embodiments and substitution of equivalents all fall within the scope of the invention. Accordingly, the invention is not to be considered as limited by the foregoing description, but instead is limited by the scope of the appended claims.

What is claimed is:

1. A semiconductor device, comprising:
a first electrode formed of a silicon-family material;
a dielectric layer formed by sequentially supplying reactants on the first electrode; and
a second electrode having a work function larger than that of the first electrode, the second electrode being formed on the dielectric layer.

2. The semiconductor device of claim 1, wherein the dielectric layer is formed of a material selected from the group consisting of an aluminum oxide, an aluminum hydroxide, Ta₂O₅, BST (BaSrTiO₃), SrTiO₃, PbTiO₃, PZT, PLZT, Y₂O₃, CeO₂, Nb₂O₅, TiO₂, ZrO₂, HfO₂, SiO₂, SiN, Si₃N₄ and combinations thereof.

3. The semiconductor device of claim 1, wherein the second electrode is formed of a member selected from the group consisting of a metal layer, a refractory metal layer, a conductive oxide layer, a combination of the above, and a double layer in which a material layer having a work function larger than that of the silicon-family material and a polysilicon layer doped with impurities are sequentially formed.

4. The semiconductor device of claim 3, wherein the metal layer is formed of a metal selected from the group consisting of Al, Ni, Co, Cu, Mo, Rh, Pd, Sn, Au, Pt, Ru, and Ir, the refractory metal layer is formed of a metal selected from the group consisting of Ti, TiN, TiAlN, TaN, TiSiN, WN, WBN, CoSi, and W, and the conductive oxide layer is formed of an oxide selected from the group consisting RuO₂, RhO₂, and IrO₂.

5. The semiconductor device of claim 1, wherein a stabilizing layer for facilitating the formation of the dielectric layer by hydrophilizing the surface of the first electrode is formed on the first electrode.

6. The semiconductor device of claim 5, wherein the stabilizing layer is a member of the group comprising a silicon oxide layer, a silicon nitride layer, and a composite layer of the silicon oxide layer and the silicon nitride layer.

7. The semiconductor device of claim 1, wherein the dielectric layer is formed by an atomic layer deposition method.

8. The semiconductor device of claim 7, wherein a reaction gas and a purging gas are sequentially supplied to a chamber in the atomic layer deposition method.

9. A semiconductor device, comprising:
a lower electrode of a capacitor formed of a silicon-family material;
a dielectric layer formed by sequentially supplying reactants on the lower electrode; and
an upper electrode of a capacitor formed on the dielectric layer and having a work function larger than that of the lower electrode.

10. The semiconductor device of claim 9, wherein the upper electrode is formed of one of a metal layer, a refractory metal layer, a conductive oxide layer, a combination of the above, and a double layer in which a material layer having a work function larger than that of the silicon-family material and a polysilicon layer doped with impurities are sequentially formed.

11. The semiconductor device of claim 9, wherein a stabilizing layer for facilitating the formation of the dielectric layer by hydrophilizing the surface of the lower electrode is formed on the lower electrode.

12. The semiconductor device of claim 11, wherein the stabilizing layer is one of a silicon oxide layer, a silicon nitride layer, and a composite layer of the silicon oxide layer and the silicon nitride layer.

13. The semiconductor device of claim 9, wherein the dielectric layer is formed by an atomic layer deposition method.

14. The semiconductor device of claim 13, wherein a reaction gas and a purging gas are sequentially supplied to a chamber in the atomic layer deposition method.

15. A semiconductor device, comprising:
a silicon substrate;
a gate insulating layer formed by sequentially supplying reactants on the silicon substrate; and
a gate electrode formed on the gate insulating layer and having a work function larger than that of the silicon substrate.

16. The semiconductor device of claim 15, wherein the gate electrode is formed of one of a metal layer, a refractory metal layer, a conductive oxide layer, a combination of the above, and a double layer in which a material layer having a work function larger than that of the silicon-family material and a polysilicon layer doped with impurities are sequentially formed.

17. The semiconductor device of claim 15, wherein a stabilizing layer for facilitating the formation of the gate insulating layer by hydrophilizing the surface of the silicon substrate is formed on the silicon substrate.

18. The semiconductor device of claim 17, wherein the stabilizing layer is one of a silicon oxide layer, a silicon nitride layer, and a composite layer of the silicon oxide layer and the silicon nitride layer.

19. The semiconductor device of claim 15, wherein the gate insulating layer is formed by an atomic layer deposition method.

20. The semiconductor device of claim 19, wherein a reaction gas and a purging gas are sequentially supplied to a chamber in the atomic layer deposition method.

21. A method for manufacturing a semiconductor device, comprising the steps of:
forming a first electrode of a silicon-family material on a semiconductor substrate;
forming a dielectric layer by sequentially supplying reactants on the first electrode; and
forming a second electrode having a work function larger than that of the first electrode, the second electrode being formed on the dielectric layer.

22. The method of claim 21, wherein the step of forming the dielectric layer includes the step of using a material selected from the group consisting of an aluminum oxide, an aluminum hydroxide, Ta₂O₅, BST (BaSrTiO₃), SrTiO₃, PbTiO₃, PZT, PLZT, Y₂O₃, CeO₂, Nb₂O₅, TiO₂, ZrO₂, HfO₂, SiO₂, SiN, Si₃N₄ and combinations thereof.

23. The method of claim 21, wherein the step of forming the second electrode includes the step of using a member selected from the group consisting of a metal layer, a refractory metal layer, a conductive oxide layer, a combination of the above, and a double layer in which a material layer having a work function larger than that of the silicon-family material and a polysilicon layer doped with impurities are sequentially formed.

24. The method of claim 23, wherein the step of using a metal layer includes the step of using a metal selected from the group consisting of Al, Ni, Co, Cu, Mo, Rh, Pd, Sn, Au, Pt, Ru, and Ir, the step of using a refractory metal layer includes the step of using a refractory metal selected from the group consisting of Ti, TiN, TiAlN, TaN, TiSiN, WN, WBN, CoSi, and W, and the step of using the conductive oxide layer includes the step of using a conductive layer formed of an oxide selected from the group consisting RuO₂, RhO₂, and IrO₂.

25. The method of claim 21, further comprising a step of forming a stabilizing layer for facilitating the formation of the dielectric layer on the first electrode after the step of forming the first electrode.

26. The method of claim 25, wherein the step of forming the stabilizing layer includes the step of selecting the stabilizing layers from one of a silicon oxide layer, a silicon nitride layer, and a composite layer of the silicon oxide layer and the silicon nitride layer.

27. The method of claim 21, wherein the step of forming the dielectric layer includes using an atomic layer deposition method.

28. The method of claim 27, wherein the atomic layer deposition method includes the steps of sequentially supplying a reaction gas and a purging gas to a chamber.

29. The method of claim 21, further comprising a step of performing post-thermal treatment after the step of forming the dielectric layer.

30. A method for manufacturing a semiconductor device, comprising the steps of:
forming a lower electrode of a capacitor of a silicon-family material on a semiconductor substrate;
forming a dielectric layer by sequentially supplying reactants on the lower electrode; and
forming an upper electrode of a capacitor having a work function larger than that of the lower electrode, the upper electrode being formed on the dielectric layer.

31. The method of claim 30, wherein the step of forming the upper electrode includes the step of forming the upper electrode from one of a metal layer, a refractory metal layer, an aluminum layer, a conductive oxide layer, a combination of the above, and a double layer in which a material layer having a work function larger than that of the silicon-family material and a polysilicon layer doped with impurities are sequentially formed.

32. The method of claim 30, further comprising a step of forming a stabilizing layer for facilitating the formation of the dielectric layer by hydrophilizing the surface of the lower electrode after the step of forming the lower electrode.

33. The method of claim 32, wherein the step of forming the stabilizing layer includes the step of forming the stabilizing electrode from one of a silicon oxide layer, a silicon nitride layer, and a composite layer of the silicon oxide layer and the silicon nitride layer.

34. The method of claim 30, wherein the step of forming the dielectric layer includes the step of using an atomic layer deposition method.

35. The method of claim 34, wherein the atomic layer deposition method includes the steps of sequentially supplying a reaction gas and a purging gas to a chamber.

36. The method of claim 30, further comprising a step of performing post-thermal treatment after the step of forming the dielectric layer.

37. A method for manufacturing a semiconductor device, comprising the steps of:
forming a gate insulating layer by sequentially supplying reactants on a silicon substrate; and
forming a gate electrode having a work function larger than that of the silicon substrate on the gate insulating layer.

38. The method of claim 37, wherein the step of forming the gate electrode includes the step of forming the gate electrode of one of a metal layer, a refractory metal layer, a conductive oxide layer, a combination of the above, and a double layer in which a material layer having a work function larger than that of the silicon-family material and a polysilicon layer doped with impurities are sequentially formed.

39. The method of claim 37, further comprising a step of forming a stabilizing layer for facilitating the formation of the gate insulating layer by hydrophilizing the silicon substrate before forming the gate insulating layer.

40. The method of claim 39, wherein the step of forming the stabilizing layer includes forming the stabilizing layer from one of a silicon oxide layer, a silicon nitride layer, and a composite layer of the silicon oxide layer and the silicon nitride layer.

41. The method of claim 37, wherein the step of forming the gate insulating layer includes using an atomic layer deposition method.

42. The method of claim 37, further comprising a step of performing post-thermal treatment after the step of forming the gate insulating layer.
